(19) United States
(12) Patent Application Publication
(10) Pub. No.: US 2026/0133660 A1
(43) Pub. Date: May 14, 2026

(54) DISPLAY PANEL AND DISPLAY DEVICE

(71) Applicants: Chongqing BOE Display Technology Co., Ltd., Chongqing (CN); BOE Technology Group Co., Ltd., Beijing (CN)

(72) Inventors: Chaojin WU, Beijing (CN); Sejun PARK, Beijing (CN)

(73) Assignees: Chongqing BOE Display Technology Co., Ltd., Chongqing (CN); BOE Technology Group Co., Ltd., Beijing (CN)

(21) Appl. No.: 19/119,110

(22) PCT Filed: Aug. 29, 2024
(86) PCT No.: PCT/CN2024/115613

§ 371 Date: Apr. 8, 2025

(30) Foreign Application Priority Data
Sep. 25, 2023 (CN) 202311246176.0

(51) Int. Cl. G06F 3/044; G06F 3/041; H10K 59/40

(52) U.S. Cl. CPC G06F 3/0446; G06F 3/04164; G06F 3/0445; H10K 59/40; G06F 2203/04111

(57) ABSTRACT

The present disclosure provides a display panel and a display device. The display panel includes a display substrate and a touch substrate. The touch substrate includes a plurality of first to fourth touch units. The first touch unit includes a plurality of first touch electrodes connected sequentially along a first direction; the second touch unit includes a plurality of second touch electrodes connected sequentially along the first direction, and an input signal of the second touch unit is inverse in polarity to that of the first touch unit; the third touch unit includes a plurality of third touch electrodes connected sequentially along a second direction, and forms a first touch capacitor with the first touch electrode; and the fourth touch unit includes a plurality of fourth touch electrodes connected sequentially along the second direction, and forms a second touch capacitor with the second touch electrode.

### CROSS-REFERENCE TO RELATED APPLICATIONS

The present disclosure is a U.S. National Stage of International Application No. PCT/CN2024/115613 filed on Aug. 29, 2024, which claims priority to Chinese patent application No. 202311246176.0 filed on Sep. 25, 2023, entitled “Display Panel and Display Device”, the entire contents of each are incorporated herein by reference.

### TECHNICAL FIELD

The present disclosure relates to the field of display technology, and specifically, to a display panel and a display device.

### BACKGROUND

The organic light-emitting display (OLED) display substrate has become the main development direction in the field of display technology due to advantages such self-illumination, high brightness, good picture quality and low energy consumption. A touch screen pane (TSP) is provided on a display surface of the display substrate. Nosie tends to be generated between the touch substrate and the display substrate, thus affecting the touch effect of the touch substrate.

It is to be noted that the information disclosed in the above-described background section is only used to enhance the understanding of the background of the present disclosure, and thus may include information that does not constitute the prior art known to a person skilled in the art.

### SUMMARY

The present disclosure provides a display panel and a display device.

An aspect of the present disclosure provides a display panel, including:
a display substrate; and
a touch substrate, provided on a light exiting side of the display substrate, wherein the touch substrate includes:
a plurality of first touch units, the first touch unit including a plurality of first touch electrodes connected sequentially along a first direction;
a plurality of second touch units, the second touch unit including a plurality of second touch electrodes connected sequentially along the first direction, and an input signal of the second touch unit being inverse in polarity to an input signal of the first touch unit;
a plurality of third touch units, the third touch unit including a plurality of third touch electrodes connected sequentially along a second direction, the third touch electrode forming a first touch capacitor with the first touch electrode, and the second direction intersecting the first direction; and
a plurality of fourth touch units, the fourth touch unit including a plurality of fourth touch electrodes connected sequentially along the second direction, and the fourth touch electrode forming a second touch capacitor with the second touch electrode.

In an exemplary embodiment of the present disclosure, an absolute value of the input signal of the second touch unit is the same as an absolute value of the input signal of the first touch unit.

In an exemplary embodiment of the present disclosure, the touch substrate includes:
a base layer, provided on the light exiting side of the display substrate;
a first touch layer, provided on a side of the base layer away from the display substrate, including a first bridging part and a second bridging part, and/or including a third bridging part and a fourth bridging part;
a touch insulating layer, provided on a side of the first touch layer away from the base layer, provided with a plurality of first via-holes and a plurality of second via-holes, and/or provided with a plurality of third via-holes and a plurality of fourth via-holes; and
a second touch layer, provided on a side of the touch insulating layer away from the base layer, and including the first touch electrode, the second touch electrode, the third touch electrode, and the fourth touch electrode,
wherein the first bridging part connects two first touch electrodes adjacent in the first direction through the first via-hole, and the second bridging part connects two second touch electrodes adjacent in the first direction through the second via-hole; and/or the third bridging part connects two third touch electrodes adjacent in the second direction through the third via-hole, and the fourth bridging part connects two fourth touch electrodes adjacent in the second direction through the fourth via-hole.

In an exemplary embodiment of the present disclosure, the display panel has a display area and a non-display area located at at least one side of the display area, and the display panel further includes:
a touch driving chip, provided in the non-display area, and electrically connected to the first touch unit, the second touch unit and the touch sensing lead,
wherein an area of an orthographic projection of the first via-hole on the base layer increases as a distance between the first via-hole and the touch driving chip increases, and an area of an orthographic projection of the second via-hole on the base layer increases as a distance between the second via-hole and the touch driving chip increases.

In an exemplary embodiment of the present disclosure, the display panel has a display area and a non-display area located at at least one side of the display area, and the display panel further includes:
a touch driving chip, provided in the non-display area, located at a side of the display area in the first direction, and electrically connected to the first touch unit, the second touch unit and the touch sensing lead,
wherein the touch substrate includes at least two first touch areas arranged sequentially along the first direction, areas of orthographic projections, on the base layer, of the first via-holes located in a same first touch area are the same, areas of orthographic projections, on the base layer, of the second via-holes located in the same first touch area are the same, areas of orthographic projections, on the base layer, of the first via-holes located in different first touch areas increase as a distance between the first touch area and the touch driving chip increases, and areas of orthographic projections, on the base layer, of the second via-holes located in the different first touch areas increase as a distance between the first touch area and the touch driving chip increases.

In an exemplary embodiment of the present disclosure, areas of orthographic projections, on the base layer, of the first via-holes connected to a same first bridging part are the same, and areas of orthographic projections, on the base layer, of the second via-holes connected to a same second bridging part are the same.

In an exemplary embodiment of the present disclosure, an area of an orthographic projection of the third via-hole on the base layer increases as a distance between the third via-hole and a connecting end of the touch sensing lead increases, and an area of an orthographic projection of the fourth via-hole on the base layer increases as a distance between the fourth via-hole and the connecting end of the touch sensing lead increases.

In an exemplary embodiment of the present disclosure, areas of orthographic projections, on the base layer, of the third via-holes connected to a same third bridging part are the same, and areas of orthographic projections, on the base layer, of the fourth via-holes connected to a same fourth bridging part are the same.

In an exemplary embodiment of the present disclosure, the touch sensing lead is connected to the third touch unit and the fourth touch unit at a side thereof in the second direction, the touch substrate includes at least two second touch areas arranged sequentially along the second direction, areas of orthographic projections, on the base layer, of the third via-holes located in a same second touch area are the same, areas of orthographic projections, on the base layer, of the fourth via-holes located in the same second touch area are the same, areas of orthographic projections, on the base layer, of the third via-holes located in different second touch areas increase as a distance between the second touch area and a connecting end of the touch sensing lead increases, and areas of orthographic projections, on the base layer, of the fourth via-holes located in the different second touch areas increase as a distance between the second touch area and the connecting end of the touch sensing lead increases.

In an exemplary embodiment of the present disclosure, the second touch electrode and the first touch electrode are provided alternatively in the first direction, and the first touch electrode includes:
two first touch sub-electrodes, sequentially arranged along the second direction, and spaced apart from each other; and
a first connecting part, connected between the two first touch sub-electrodes, and
the second touch electrode includes:
two second touch sub-electrodes, sequentially arranged along the second direction, and spaced apart from each other; and
a second connecting part, connected between the two second touch sub-electrodes.

In an exemplary embodiment of the present disclosure, the second touch layer further includes:
a first connecting wire, spaced apart from the two first touch sub-electrodes, provided between the two first touch sub-electrodes, having an end connected to the second connecting part and another opposite end connected to the second bridging part to connect two second touch electrodes adjacent in the first direction; and
a second connecting wires, spaced apart from the two second touch sub-electrodes, provided between the two second touch sub-electrodes, having an end connected to the first connecting part and another opposite end connected to the first bridging part to connect two first touch electrodes adjacent in the first direction.

In an exemplary embodiment of the present disclosure, the second touch electrode is staggered with the first touch electrode, and the first touch unit and the second touch unit are arranged alternatively in the second direction.

In an exemplary embodiment of the present disclosure, at least two adjacent third touch units form a group, and the third touch units in the group form a plurality of first touch capacitors with the plurality of first touch electrodes arranged in a row along the second direction; and at least two adjacent fourth touch units form a group, and the fourth touch units in the group form a plurality of second touch capacitors with the plurality of second touch electrodes arranged in a row along the second direction.

In an exemplary embodiment of the present disclosure, one third touch electrode is spaced apart from and provided adjacent to two adjacent first touch electrodes to form the first touch capacitor, and one fourth touch electrode is spaced apart from and provided adjacent to two adjacent second touch electrodes to form the second touch capacitor.

In an exemplary embodiment of the present disclosure, the touch substrate further includes a plurality of touch sensing leads, a plurality of first touch driving leads and a plurality of second touch driving leads; each of the first touch driving leads is connected to an end of the first touch unit, and each of the second touch driving leads is connected to an end of the second touch unit; or two of the first touch driving leads are correspondingly connected to opposite ends of the first touch unit, and two of the second touch driving leads are correspondingly connected to opposite ends of the second touch unit, and
each of the touch sensing leads is least connected to the third touch unit and the fourth touch unit adjacent to each other.

In an exemplary embodiment of the present disclosure, the third touch unit and the fourth touch unit adjacent to each other are a group of touch sensing units, and two ends of the touch sensing unit in the second direction each is connected to the touch sensing lead.

In an exemplary embodiment of the present disclosure, the plurality of first touch units are sequentially arranged along the second direction, the plurality of second touch units are sequentially arranged along the second direction, the plurality of third touch units are sequentially arranged along the first direction, and the plurality of fourth touch units are sequentially arranged along the first direction.

Another aspect of the present disclosure provides a display device, including any of the above-described display panels.

It is to be understood that the above general description and the following detailed description are exemplary and explanatory only, which do not limit the present disclosure.

### BRIEF DESCRIPTION OF THE DRAWINGS

The accompanying drawings herein are incorporated into and form a part of the specification, illustrate embodiments consistent with the present disclosure, and are used in conjunction with the specification to explain the principle of the present disclosure. Obviously, the accompanying drawings in the following description are only some of the embodiments of the present disclosure, and a person skilled in the art may obtain other drawings from these drawings without creative labor.

FIG. 1 is a schematic structural diagram showing area-dividing of a display panel in the present disclosure.

FIG. 2 is a schematic structural diagram of the display panel of FIG. 1 after being bent.

FIG. 3 is a cross-section view of a structure of a display area of the display panel of FIG. 1 according to an example embodiment.

FIG. 4 is a schematic structural diagram of a touch substrate in a display panel according to an example embodiment of the present disclosure.

FIG. 5 is a schematic structural diagram of a touch substrate in a display panel according to another example embodiment of the present disclosure.

FIG. 6 is a schematic structural diagram of a first touch electrode and a second touch electrode in FIG. 5.

FIG. 7 is a schematic structural diagram of a touch substrate in a display panel according to yet another example embodiment of the present disclosure.

FIG. 8 is a schematic structural diagram of a first touch electrode and a second touch electrode in FIG. 7.

FIG. 9 is a schematic structural diagram of a first bridging part, a second bridging part, a first via-hole and a second via-hole in FIGS. 4 and 5 according to an example embodiment.

FIG. 10 is a schematic structural diagram of a third bridging part, a fourth bridging part, a first via-hole and a second via-hole in FIGS. 4 and 5 according to an example embodiment.

FIG. 11 is a schematic structural diagram of a first bridging part, a second bridging part, a first via-hole and a second via-hole in FIGS. 4 and 5 according to another example embodiment.

FIG. 12 is a schematic structural diagram of a third bridging part, a fourth bridging part, a first via-hole and a second via-hole in FIGS. 4 and 5 according to another example embodiment.

### DETAILED DESCRIPTION

Example embodiments will now be described more fully with reference to the accompanying drawings. However, the example embodiments may be implemented in a variety of forms and should not be construed as being limited to the embodiments set forth herein; rather, these embodiments are provided so that the present disclosure is comprehensive and complete and conveys the idea of the example embodiments comprehensively to a person skilled in the art. The same reference numerals denote the same or similar structures in the drawings, and thus their detailed descriptions will be omitted. In addition, the accompanying drawings are only schematic illustrations of the present disclosure and are not necessarily drawn to scale.

Although relative terms such as “on” and “under” are used in this specification to describe the relative relationship of one component to another component shown, these terms are used in this specification only for convenience of description, for example, based on the example direction shown in the accompanying drawings. It will be appreciated that if a device shown is turned upside down, the component described as being “on” will become the component described as being “under”. When a structure is “on” another structure, it may mean that the structure is integrally formed on the another structure, or that the structure is “directly” provided on the another structure, or that the structure is “indirectly” provided on the another structure through an additional structure.

The terms “a”, “an”, “the”, “said” and “at least one of . . . ” are used to indicate the presence of one or more elements/components/etc.; the terms “include/comprise” and “have” are used to indicate open-ended inclusion and mean that there may be additional elements/components/etc. in addition to those listed; and the terms “first”, “second” and “third”, etc. are used only as indications not to limit the quantity of the objects thereof.

In the present disclosure, unless otherwise expressly provided and limited, the term “connect” is to be understood in a broad sense, e.g., the “connect” may be a fixed connection, a detachable connection, or an integral connection; and it may be a direct connection or an indirect connection through an intermediate medium. The “and/or” is merely a description of an association of associated objects, indicating that there may three kinds of relationships, for example, A and/or B, which may mean: A alone, both A and B, and B alone. In addition, the character “/” herein generally indicates that the associated objects are in an “or” relationship.

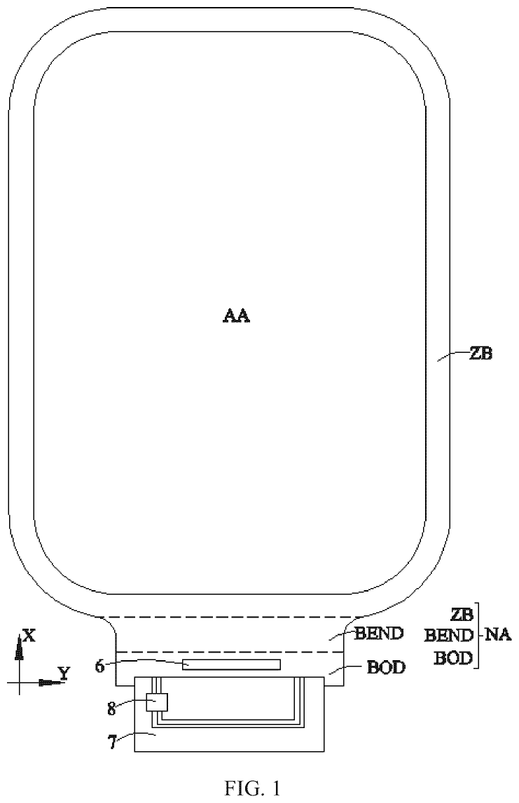

An example embodiment of the present disclosure provides a display panel, as shown in FIGS. 1 to 12, which may include a display substrate 10 and a touch substrate 20. The touch substrate 20 is provided on a light exiting side of the display substrate 10, and the touch substrate 20 includes a plurality of first touch units 201, a plurality of second touch units 202, a plurality of third touch units 203, and a plurality of fourth touch units 204. The first touch unit 201 may include a plurality of first touch electrodes 541 sequentially connected along a first direction X. The second touch unit 202 may include a plurality of second touch electrodes 542 sequentially connected along the first direction X, and an input signal of the second touch unit 202 is inverse in polarity to an input signal of the first touch unit 201. The third touch unit 203 may include a plurality of third touch electrodes 542 sequentially connected along a second direction Y, the third touch electrode 543 forms a first touch capacitor with the first touch electrode 541, and the second direction Y intersects the first direction X. The fourth touch unit 204 may include a plurality of fourth touch electrodes 544 sequentially connected along the second direction Y, and the fourth touch electrode 544 forms a second touch capacitor with the second touch electrode 542.

In the display panel of the present disclosure, the input signal of the second touch unit 202 is inverse in polarity to the input signal of the first touch unit 201, therefore when the display substrate 10 realizes a display function and power is applied to a second electrode 34, first noise generated by the second electrode 34 and the first touch unit 201 is inverse in polarity to second noise generated by the second electrode 34 and the second touch unit 202, and the first noise and the second noise with inverse polarities may at least partially cancel each other out, so that the noise of the touch signal is less or even there is no noise.

Referring to FIG. 1, the display panel may include a display area AA in which an image is displayed and a non-display area AA in which the image is not displayed, and the touch function may be implemented in the display area AA. The non-display area AA may include a peripheral area ZB, and the peripheral area ZB may be arranged to surround the display area AA and may also include a bending area BEND for bending and a binding area BOD for binding. The bending area BEND is connected to the peripheral area ZB, and the binding area BOD is connected to the bending area BEND.

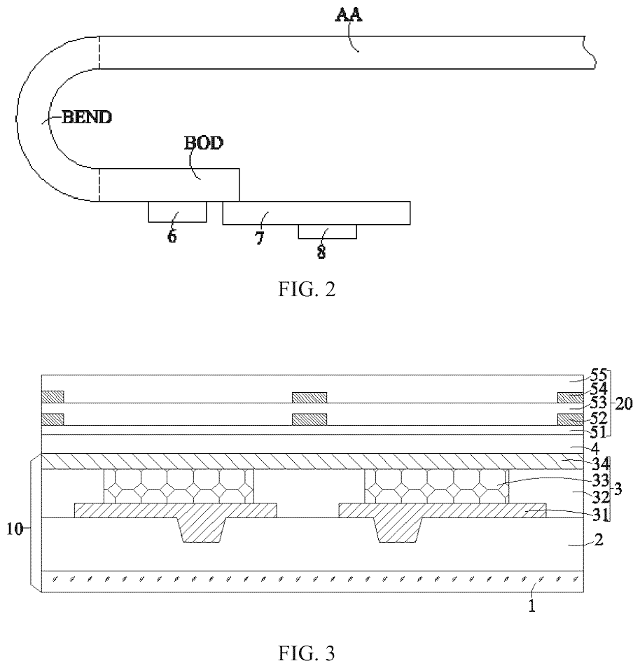

Referring to FIG. 2, the display panel may be bent at the bending area BEND such that the binding area BOD is located at a side of the display area AA away from the display surface.

A binding pin is provided in the binding area BOD, and an external device may be mounted on (or attached to) the binding pin. The external device may include a display driving chip 6, a touch driving chip 8, a flexible printed circuit board 7 or a rigid printed circuit board, and the like. Further, a Chip On Flex or Chip On Film (COF), a connector, and the like may be mounted on the binding pin as the external device. One external device or a plurality of external devices may be mounted in the binding area BOD.

The touch driving chip 8 may be mounted on the same surface of the flexible printed circuit board 7 as the display surface. Referring to FIG. 2, when the bending area BEND is bent to be reversed, the display driving chip 6 and the touch driving chip 8 are located on a side of the display panel away from the display surface.

The touch driving chip 8 may be bonded to the flexible printed circuit board 7 by an anisotropic conductive adhesive, or may be attached to the flexible printed circuit board 7 by ultrasonic bonding.

The touch driving chip 8 may include an integrated circuit that drives the touch substrate 20. In an embodiment, the integrated circuit may be a touch driving integrated circuit that generates and provides a touch driving signal, but the present disclosure is not limited thereto. The touch driving chip 8 is connected to the binding pin of the display panel to provide the touch driving signal to the binding pin and to receive the touch sensing signal from the touch substrate 20.

Referring to FIG. 3, the display panel may include a display substrate 10, the display substrate 10 may include a base substrate 1, a driving backplane 2, and a light-emitting substrate 3, and the driving backplane 2 may drive the light-emitting substrate 3 to emit light. The driving backplane 2 is provided on a side of the base substrate 1, and the light-emitting substrate 3 is provided on a side of the driving backplane 2 away from the base substrate 1. The touch substrate 20 may be provided on the light exiting side of the display substrate 10, i.e., the touch substrate 20 is provided on the side of the light-emitting substrate 3 away from the base substrate 1. A polarizer may be provided on a side of the touch substrate 20 away from the display substrate 10, and a cover plate may be provided on a side of the polarizer away from the display substrate 10.

The display substrate 10 may be an OLED (Organic Electroluminescence Display) display substrate 10, a QLED (Quantum Dot Light Emitting Diodes) display substrate 10, a Micro-LED (Micro-Light Emitting Diode) display substrate 10 and the like. The display substrate 10 has a light exiting side and a non-light exiting side opposite to each other, the light exiting side may display a picture, and the surface for displaying the picture is a display surface.

In an example embodiment, taking the OLED display substrate 10 as an example, the driving backplane 2 may include a plurality of switching units, the switching unit may include a plurality of thin-film transistors, and the plurality of switching units are arranged in an array. A first planarization layer is provided at a side of the plurality of switching units away from the base substrate 1, and the first planarization layer provides a relatively flat base surface for a film layer to be formed subsequently.

The light-emitting substrate 3 is provided on a side of the first planarization layer away from the base substrate 1, and may include a first electrode 31, a pixel defining layer 32, a light-emitting layer group 33, and a second electrode 34.

Specifically, the first electrode 31 is provided on a side of the first planarization layer away from the base substrate 1, and is connected to a source electrode of the driving backplane 2, and the first electrode 31 may be an anode.

The pixel defining layer 32 is provided on a side of the first electrode 31 away from the base substrate 1, and is provided with a via-hole. The light-emitting layer group 33 is provided within the via-hole. The second electrode 34, which may be a cathode, is provided on a side of the light-emitting layer group 33 away from the base substrate 1, and is connected to a ground line VSS. The light-emitting layer group 33 within one via-hole emits light and forms one sub-pixel, therefore the light-emitting layer group 33 within one via-hole is one sub-pixel, so that the orthographic projection of the sub-pixel on the display substrate 10 is the orthographic projection of the light-emitting layer group 33 on the display substrate 10, and the display substrate 10 may include a plurality of sub-pixels.

The light-emitting layer group 33 may include a hole injection layer, a hole transport layer, a light-emitting layer, an electron transport layer, and an electron injection layer stacked in that order. The hole injection layer is in contact with the first electrode 31, and the electron injection layer is in contact with the second electrode 34. Of course, in other exemplary embodiments of the present disclosure, the light-emitting layer group 33 may include only the hole transport layer, the light-emitting layer, and the electron transport layer, and the light-emitting layer group 33 may also be of other structures, and the specific structure thereof may be set according to the need.

The display substrate 10 may also include an encapsulation layer group 4. The encapsulation layer group 4 is provided on a side of the second electrode 34 away from the base substrate 1 to encapsulate the display substrate 10, so as to avoid outside water vapor, impurities, and the like from entering into the inside of the display substrate 10, which affects the display effect of the display substrate 10. The encapsulation layer group 4 may be provided as a multilayer, and the encapsulation layer group 4 may include an organic layer and an inorganic layer, specifically, the encapsulation layer group 4 may include a first inorganic layer, an organic layer provided on a side of the first inorganic layer away from the base substrate 1, and a second inorganic layer provided on a side of the organic layer away from the base substrate 1. The materials of the first inorganic layer, the organic layer, and the second inorganic layer are not described herein. Of course, the encapsulation layer group 4 may also include more or fewer layers.

In an example embodiment, referring to FIG. 3, the touch substrate 20 is provided on a side of the encapsulation layer group 4 away from the base substrate 1.

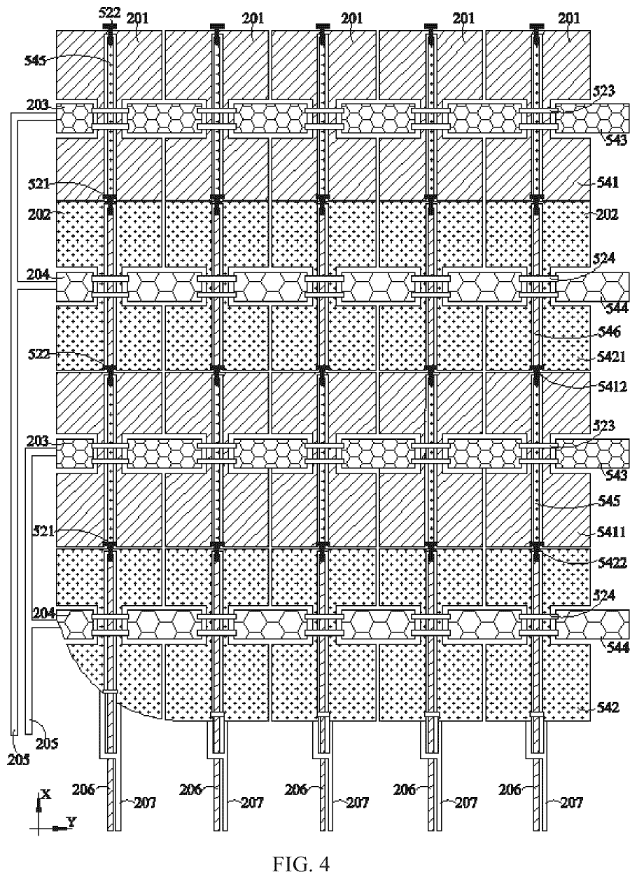

Referring to FIG. 4, the touch substrate 20 may include a plurality of first touch units 201, a plurality of second touch units 202, a plurality of third touch units 203, a plurality of fourth touch units 204, a plurality of touch sensing leads 205, a plurality of first touch driving leads 206, and a plurality of second touch driving leads 207.

The first touch unit 201 may include a plurality of first touch electrodes 541 sequentially connected along the first direction X, and the plurality of first touch units 201 are sequentially arranged along the second direction Y, such that the plurality of first touch electrodes 541 are arranged in an array. Two first touch electrodes 541 adjacent in the second direction Y are spaced apart from each other and are not connected with each other. Two first touch electrodes 541 adjacent in the first direction X are provided with a gap therebetween and are connected to form the first touch unit 201 extending along the first direction X.

The second touch unit 202 may include a plurality of second touch electrodes 542 sequentially connected along the first direction X, and the plurality of second touch units 202 are sequentially arranged along the second direction Y, such that the plurality of second touch electrodes 542 are arranged in an array. Two second touch electrodes 542 adjacent in the second direction Y are spaced apart from each other and are not connected with each other. Two second touch electrodes 542 adjacent in the first direction X are provided with a gap therebetween and are connected to form the second touch unit 202 extending along the first direction X.

Moreover, the second touch electrode 542 is provide within the gap between two adjacent first touch electrodes 541, and similarly, the first touch electrode 541 is disposed within the gap between two adjacent second touch electrodes 542, such that the second touch electrode 542 and the first touch electrode 541 are provided alternately in the first direction X.

The second direction Y intersects the first direction X. For example, the second direction Y is perpendicular to the first direction X.

That is, the plurality of first touch electrodes 541 are arranged in the second direction Y to form a first touch electrode row, the plurality of second touch electrodes 542 are arranged in the second direction Y to form a second touch electrode row, and the first touch electrode row and the second touch electrode row are provided alternately in the first direction X. The plurality of first touch electrodes 541 within the first touch electrode row are spaced apart from each other and not connected with each other, and the plurality of second touch electrodes 542 within the second touch electrode row are spaced apart from each other and not connected with each other. Two first touch electrodes 541 adjacent in the first direction X are connected such that the plurality of first touch electrodes 541 in the first direction X are connected to form the first touch unit 201 extending along the first direction X. Two second touch electrodes 542 adjacent in the first direction X are connected such that the plurality of second touch electrodes in the first direction X are connected to form the second touch unit 202 extending along the first direction X.

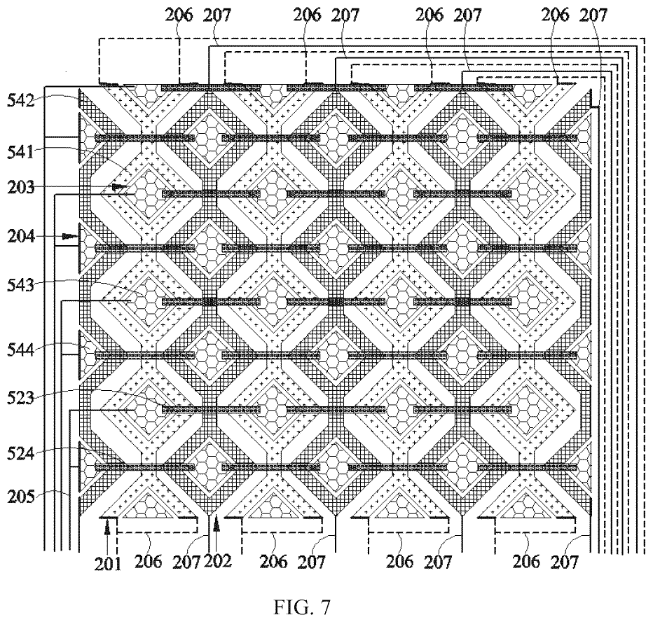

Of course, in some other example embodiments of the present disclosure, referring to FIG. 7, the second touch electrodes 542 and the first touch electrodes 541 may not be provided alternately in the first direction X, but the second touch electrode 542 and the first touch electrode 541 are staggered with each other, such that the first touch unit 201 may include a plurality of first touch electrodes 541 sequentially connected along the first direction X, and the second touch unit 202 may include a plurality of second touch electrodes 542 connected sequentially along the first direction X.

The input signal of the second touch unit 202 is inverse in polarity to the input signal of the first touch unit 201. Specifically, the first touch unit 201 is input with a signal through the first touch driving lead 206, and the second touch unit 202 is input with a signal through the second touch driving lead 207, i.e., the first touch unit 201 and the second touch unit 202 are input with signals through different leads, so that the input signal of the second touch unit 202 may be different from the input signal of the first touch unit 201.

The input signal of the second touch unit 202 is inverse in polarity to the input signal of the first touch unit 201. For example, in the case where the input signal is a sinusoidal signal, a phase of the input signal of the second touch unit 202 is inverse to that of the input signal of the first touch unit 201, i.e., there is a phase difference of x between the input signal of the second touch unit 202 and the input signal of the first touch unit 201 such that the input signal of the second touch unit 202 is inverse in polarity to the input signal of the first touch unit 201 at each non-zero moment. Of course, the input signal of the second touch unit 202 and the input signal of the first touch unit 201 may also be rectangular wave signals and the like, which is will not be described in detail herein.

Referring to FIGS. 4 and 7, the third touch unit 203 may include a plurality of third touch electrodes 543 sequentially connected along the second direction Y, and the plurality of third touch units 203 are sequentially arranged along the first direction X, so that the plurality of third touch electrodes 543 are arranged in an array. Two third touch electrodes 543 adjacent in the first direction X are spaced apart from each other and are not connected with each other. Two third touch electrodes 543 adjacent in the second direction Y are provided with a gap therebetween and are connected to form the third touch unit 203 extending along the second direction Y.

The third touch electrode 543 forms a first touch capacitor with the first touch electrode 541, specifically, the third touch electrode 543 is embedded in the first touch electrode 541, i.e., the third touch electrode 543 is surrounded by the first touch electrode 541, and the third touch electrode 543 is spaced apart from the first touch electrode 541 and is not connected therewith, so that the third touch electrode 543 and the first touch electrode 541 form the first touch capacitor, and a plurality of first touch capacitors are sequentially arranged along the second direction Y to form a first touch capacitor row.

The fourth touch unit 204 may include a plurality of fourth touch electrodes 544 connected sequentially along the second direction Y, and the plurality of fourth touch units 204 are sequentially arranged along the first direction X, such that the plurality of fourth touch electrodes 544 are arranged in an array. Two fourth touch electrodes 544 adjacent in the first direction X are spaced apart from each other and are not connected with each other. Two fourth touch electrodes 544 adjacent in the second direction Y are provided with a gap therebetween and are connected to form the fourth touch unit 204 extending along the second direction Y.

The fourth touch electrode 544 forms a second touch capacitor with the second touch electrode 542, specifically, the fourth touch electrode 544 is embedded in the second touch electrode 542, i.e., the fourth touch electrode 544 is surrounded by the second touch electrode 542, and the fourth touch electrode 544 is spaced apart from the second touch electrode 542 and is not connected therewith, so that the fourth touch electrode 544 and the second touch electrode 542 form the second touch capacitor, and a plurality of second touch capacitors are sequentially arranged along the second direction Y to form a second touch capacitor row.

The first touch capacitor row and the second touch capacitor row are arranged alternately, i.e., one second touch capacitor row is provided between two adjacent first touch capacitor rows, and one first touch capacitor row is provided between two adjacent second touch capacitor rows.

The touch principle is that each of the first touch capacitor and the second touch capacitor has a different position in the touch substrate 20, that is, each of the first touch capacitor and the second touch capacitor is located at a different point in a coordinate system including the first direction X and the second direction Y. The touch driving chip 8 transmits touch driving signals (e.g., trigger signals) to the plurality of first touch units 201 and the plurality of second touch units 202. At this time, there is an initial capacitance value on each of the first touch capacitors and the second touch capacitors at the different positions described above. Since a human body is a conductor, when a human finger touches a position of the touch substrate 20, the capacitance value of the first touch capacitor and/or the second touch capacitor at that position will change. Based on the amount of change in the capacitance value, a corresponding touch sensing signal (e.g., a reception signal) may be received on the third touch electrode 543 and/or the fourth touch electrode 544 at that position. The touch sensing signal on the third touch electrode 543 and/or the fourth touch electrode 544 at that position is transmitted to the touch driving chip 8. The capacitance values of the first touch capacitor and the second touch capacitor at the untouched position remain unchanged. Therefore, by determining the amount of change in the capacitance value on each of the first touch capacitor and the second touch capacitor, the touch point may be determined, thereby achieving the touch function.

The encapsulation layer group 4 is provided between the touch substrate 20 and the second electrode 34, and the encapsulation layer group 4 is thin and is an insulating layer, therefore a noise capacitor may be formed between the touch substrate 20 and the second electrode 34. When the display substrate 10 realizes a display function, power is applied to the second electrode 34, so that the capacitance value on the noise capacitor changes, thereby generating a noise that affects the touch effect of the touch substrate 20. For example, if the noise is large, even though no touch operation occurs, a touch signal may also be generated on the touch substrate 20, thereby outputting the touch signal, and leading to a touch misjudgment.

Each touch sensing lead 205 is at least connected to the third touch unit 203 and the fourth touch unit 204 adjacent to each other, i.e., a single touch sensing lead 205 is at least connected to a first touch capacitor row and a second touch capacitor row adjacent to each other, such that electrical signals from the first touch capacitor row and the second touch capacitor row are outputted through the single touch sensing lead 205.

Moreover, the input signal of the second touch unit 202 is inverse in polarity to the input signal of the first touch unit 201, therefore when the display substrate 10 realizes a display function and power is applied to the second electrode 34, first noise generated by the second electrode 34 and the first touch unit 201 is inverse in polarity to second noise generated by the second electrode 34 and the second touch unit 202, and the first noise and the second noise with inverse polarities may at least partially cancel each other out after being connected by the touch sensing lead 205, so that the noise of the touch signal transmitted from the touch sensing lead 205 to the touch driving chip 8 is less or even there is no noise.

Further, an absolute value of the input signal of the second touch unit 202 is substantially the same as an absolute value of the input signal of the first touch unit 201, i.e., numerical values of the input signal of the second touch unit 202 and the input signal of the first touch unit 201 are the same, but have inverse polarities. Therefore, the first noise generated by the second electrode 34 and the first touch unit 201 and the second noise generated by the second electrode 34 and the second touch unit 202 are inverse in polarity but have substantially the same numerical value, and the first noise and the second noise with inverse polarities but substantially the same numerical value may almost completely cancel each other out after being connected by the touch sensing lead 205, so that the touch signal transmitted from the touch sensing lead 205 to the touch driving chip 8 has no noise, thereby further improving the touch effect of the touch substrate 20, and avoiding a touch misjudgment.

It is to be noted that the absolute value of the input signal of the second touch unit 202 is the same as the absolute value of the input signal of the first touch unit 201, which not only includes the case where the absolute value of the input signal of the second touch unit 202 is identical to the absolute value of the input signal of the first touch unit 201, but also includes the case where there may be a certain error between the absolute value of the input signal of the second touch unit 202 and the absolute value of the input signal of the first touch unit 201, and within such error range, the absolute value of the input signal of the second touch unit 202 is considered to be the same as the absolute value of the input signal of the first touch unit 201. The error range may be set according to the manufacturing precision of the display panel and the precision of the touch driving chip 8.

Of course, in some other exemplary embodiments of the present disclosure, the third touch unit 203 and the fourth touch unit 204 adjacent to each other may be connected via other connecting wires, then the connecting wire is connected to the touch sensing lead 205, and the touch sensing signal is outputted via the touch sensing lead 205 to the touch driving chip 8. In a possible embodiment, the plurality of the third touch units 203 and the plurality of the fourth touch units 204 may be respectively connected to the touch driving chip 8 via respective touch sensing leads 205, and the first noise and the second noise cancel each other out at the touch driving chip 8.

The overall structure of the touch substrate 20 has been described above, and the individual film layers of the touch substrate 20 are described below.

Referring to FIG. 3, the touch substrate 20 may include a base layer 51, a first touch layer 52, a touch insulating layer 53, a second touch layer 54, and a protective layer 55 which are stacked.

The first touch layer 52 is provided on a side of the base layer 51, specifically, the first touch layer 52 is provided on a side of the base layer 51 away from the display substrate 10. The first touch layer 52 may include a first bridging part 521, a second bridging part 522, a third bridging part 523, and a fourth bridging part 524.

The touch insulating layer 53 is provided on a side of the first touch layer 52 away from the base layer 51, and the touch insulating layer 53 is provided with a plurality of first via-holes 531, a plurality of second via-holes 532, a plurality of third via-holes 533, and a plurality of fourth via-holes 534.

The second touch layer 54 is provided on a side of the touch insulating layer 53 away from the base layer 51, and the second touch layer 54 may include a first touch electrode 541, a second touch electrode 542, a third touch electrode 543, and a fourth touch electrode 544.

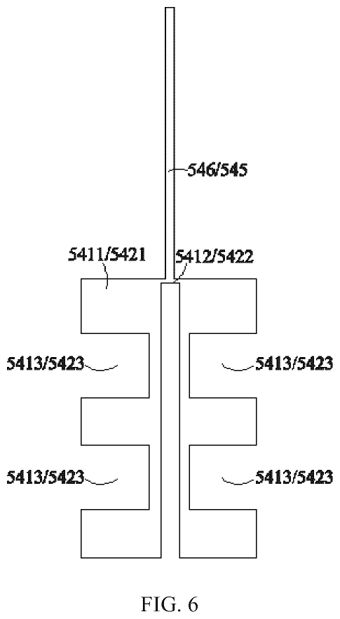

Referring to FIGS. 4, 5, and 6, the first touch electrode 541 and the second touch electrode 542 have substantially the same structure, and both the first touch electrode 541 and the second touch electrode 542 are represented in FIG. 6.

Specifically, the first touch electrode 541 may be provided in a rectangular shape, and the first touch electrode 541 may include a first connecting part 5412 and two first touch sub-electrodes 5411. The first touch sub-electrode 5411 may also be provided in a rectangular shape, and the two first touch sub-electrodes 5411 are arranged sequentially along the second direction Y and spaced apart from each other. The first connecting part 5412 is connected between the two first touch sub-electrodes 5411, and is connected to ends of the two first touch sub-electrodes 5411 adjacent to the second touch electrode 542.

The second touch electrode 542 may be provided in a rectangular shape, and the second touch electrode 542 may include a second connecting part 5422 and two second touch sub-electrodes 5421. The second touch sub-electrode 5421 may also be provided in a rectangular shape, and the two second touch sub-electrodes 5421 are arranged sequentially along the second direction Y and spaced apart from each other. The second connecting part 5422 is connected between the two second touch sub-electrodes 5421, and is connected to ends of the two second touch sub-electrodes 5421 adjacent to the first touch electrode 541.

The second touch layer 54 may further include a first connecting wire 545 and a second connecting wire 546. The first connecting wire 545 is spaced apart from the two first touch sub-electrodes 5411 and is provided therebetween, i.e., the first connecting wire 545 is spaced apart from the two first touch sub-electrodes 5411 and is not connected thereto. An end of the first connecting wire 545 is connected to the second connecting part 5422, and the first connecting wire 545 extends away from the second connecting part 5422 and in between the two first touch sub-electrodes 5411. Two second touch electrodes 542 adjacent in the first direction X may be connected by the first connecting wire 545.

The second connecting wire 546 is spaced apart from the two second touch sub-electrodes 5421 and is provided therebetween, i.e., the second connecting wire 546 is spaced apart from the two second touch sub-electrodes 5421 and is not connected thereto. An end of the second connecting wire 546 is connected to the first connecting part 5412, and the second connecting wire 546 extends away from the first connecting part 5412 and in between the two second touch sub-electrodes 5421. Two first touch electrodes 541 adjacent in the first direction X may be connected by the second connecting wire 546.

Both sides of the first touch electrode 541 in the second direction Y are provided with a first recessed part 5413, and the third touch electrode 543 is provided within the first recessed part 5413, specifically, the third touch electrode 543 located at the edge position is provided within the first recessed part 5413 of one first touch electrode 541, and the third touch electrode 543 located at the non-edge position is provided within two first recessed parts 5413 of two adjacent first touch electrodes 541, so that one third touch electrode 543 is spaced apart from the two adjacent first touch electrodes 541 and is provided adjacent thereto to form first touch capacitors, i.e., the one third touch electrode 543 forms the first touch capacitor with each of the two adjacent first touch electrodes 541 to increase the density of the first touch capacitor, thereby increasing the touch accuracy.

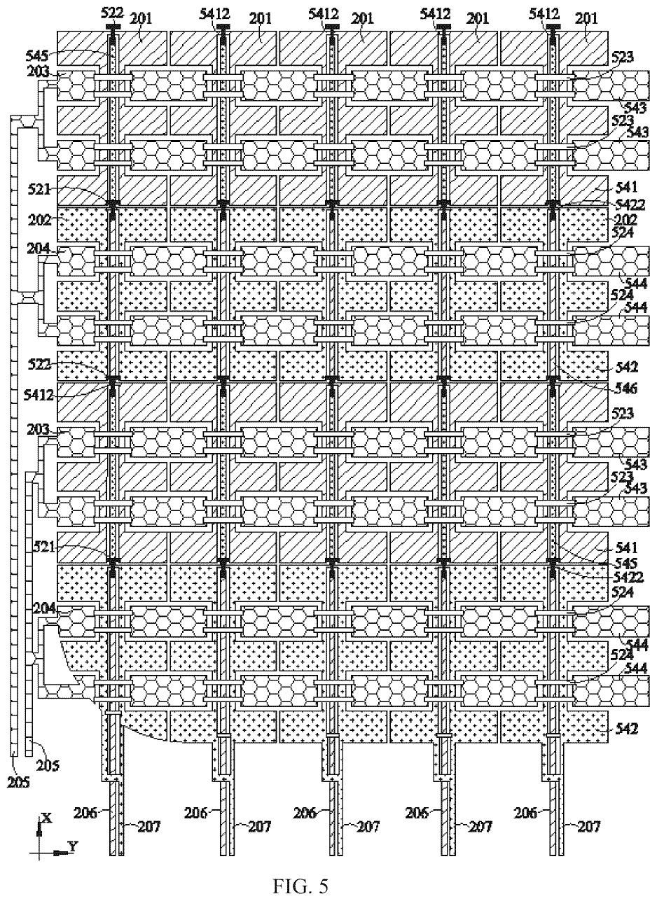

Further, referring to FIGS. 5 and 6, each side of the first touch electrode 541 in the second direction Y is provided with two first recessed parts 5413, and the third touch electrode 543 is provided within the first recessed part 5413, such that two third touch electrodes 543 are provided between two first touch electrodes 541 adjacent in the second direction Y, and the two third touch electrodes 543 are arranged along the first direction X. A row of the third touch electrodes 543 arranged along the second direction Y and connected to each other forms one third touch unit 203, then two rows of the third touch electrodes 543 arranged along the second direction Y and connected to each other form two third touch units 203. Two adjacent third touch units 203 form a group, and the group of third touch units 203 is connected to a plurality of first touch electrodes 541 arranged in a row along the second direction Y to form a plurality of first touch capacitors, i.e., two rows of third touch electrodes 543 arranged along the second direction Y form the first touch capacitors with one row of first touch electrodes 541 arranged along the second direction Y, which can also increase the density of the first touch capacitors, thereby increasing the touch accuracy.

Of course, in some other exemplary embodiments of the present disclosure, each side of the first touch electrode 541 in the second direction Y may be provided with three or more first recessed parts 5413, and the third touch electrodes 543 are provided within the first recessed parts 5413. Therefore, three or more rows of the third touch electrodes 543 arranged along the second direction Y form the first touch capacitors with one row of the first touch electrodes 541 arranged along the second direction Y, which can also increase the density of the first touch capacitors, thereby increasing the touch accuracy.

Both sides of the second touch electrode 542 in the second direction Y are provided with a second recessed part 5423, and the fourth touch electrode 544 is provided within the second recessed part 5423, specifically, the fourth touch electrode 544 located at the edge position is provided within the second recessed part 5423 of one second touch electrode 542, and the fourth touch electrode 544 located at the non-edge position is provided within two second recessed parts 5423 of two adjacent second touch electrodes 542, so that one fourth touch electrode 544 is spaced apart from the two adjacent second touch electrodes 542 and is provided adjacent thereto to form second touch capacitors, i.e., the one fourth touch electrode 544 forms the second touch capacitor with each of the two adjacent second touch electrodes 542 to increase the density of the second touch capacitor, thereby increasing the touch accuracy.

Further, referring to FIGS. 5 and 6, each side of the second touch electrode 542 in the second direction Y is provided with two second recessed parts 5423, and the fourth touch electrode 544 is provided within the second recessed part 5423, such that two fourth touch electrodes 544 are provided between two second touch electrodes 542 adjacent in the second direction Y, and the two fourth touch electrodes 544 are arranged along the first direction X. A row of the fourth touch electrodes 544 arranged along the second direction Y and connected to each other forms one fourth touch unit 204, then two rows of the fourth touch electrodes 544 arranged along the second direction Y and connected to each other form two fourth touch units 204. Two adjacent fourth touch units 204 form a group, and the group of fourth touch units 204 is connected to a plurality of second touch electrodes 542 arranged in a row along the second direction Y to form a plurality of second touch capacitors, i.e., two rows of fourth touch electrodes 544 arranged along the second direction Y form the second touch capacitors with one row of second touch electrodes 542 arranged along the second direction Y, which can also increase the density of the second touch capacitors, thereby increasing the touch accuracy.

Of course, in some other exemplary embodiments of the present disclosure, each side of the second touch electrode 542 in the second direction Y may be provided with three or more second recessed parts 5423, and the fourth touch electrodes 544 are provided within the second recessed parts 5423. Therefore, three or more rows of the fourth touch electrodes 544 arranged along the second direction Y form the second touch capacitors with one row of the second touch electrodes 542 arranged along the second direction Y, which can also increase the density of the second touch capacitors, thereby increasing the touch accuracy.

In an example embodiment, the first recessed part 5413 and the second recessed part 5423 are both provided in a rectangular shape. Of course, the first recessed part 5413 and the second recessed part 5423 may also be provided as a semi-circle, a semi-oval, a triangle, and the like.

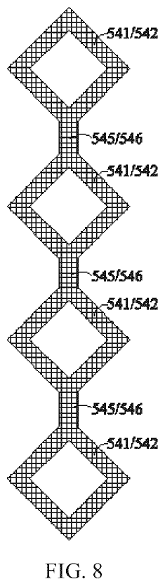

Referring to FIGS. 7 and 8, the first touch electrode 541 and the second touch electrode 542 may be provided in the form of a rhombic ring, with corner parts of two adjacent first touch electrodes 541 being provided opposite to each other, and corner parts of two adjacent second touch electrodes 542 being provided opposite to each other, so that a portion of the second touch electrode 542 may be located between the two adjacent first touch electrodes 541, and a portion of the first touch electrode 541 may be located between the two adjacent second touch electrodes 542. Therefore, the first touch electrode 541 and the second touch electrode 542 are staggered with each other.

The third touch electrode 543 is provided within the ring of the first touch electrode 541, such that the third touch electrode 543 and the first touch electrode 541 may form a first touch capacitor, and the fourth touch electrode 544 is provided within the ring of the second touch electrode 542, such that the fourth touch electrode 544 and the second touch electrode 542 may form a second touch capacitor.

Moreover, a first connecting wire 545 is connected between two first touch electrodes 541 adjacent in the first direction X, such that the plurality of first touch electrodes 541 arranged along the first direction X are sequentially connected to form the first touch unit 201. A second connecting wire 546 is connected between two second touch electrodes 542 adjacent in the first direction, such that the plurality of second touch electrodes 542 arranged along the first direction X are sequentially connected to form a second touch unit. Both the first touch electrode 541 and the second connecting wire 546 are provided in the second touch layer 54.

Referring to FIGS. 4 to 6 and FIGS. 9 and 10, FIGS. 4 to 6 illustrate respective bridging parts, but do not illustrate the via-hole due to the small size thereof;

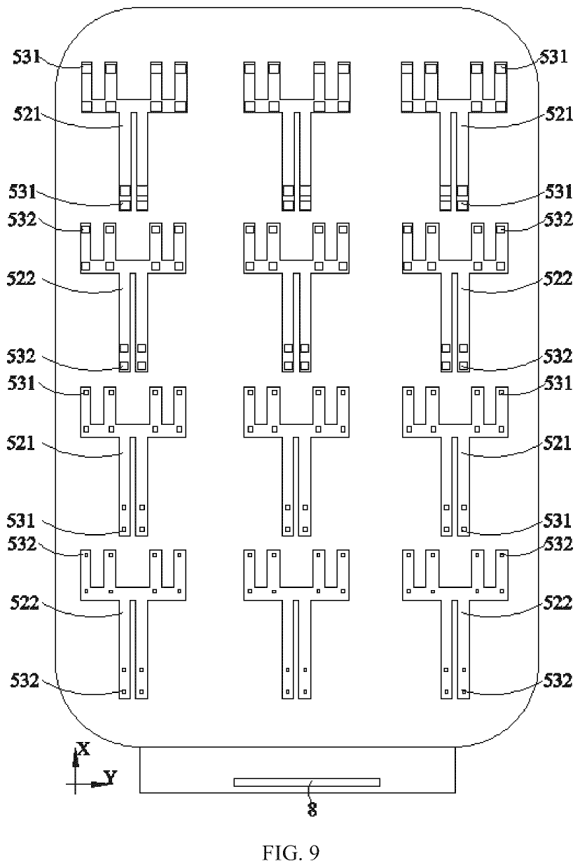

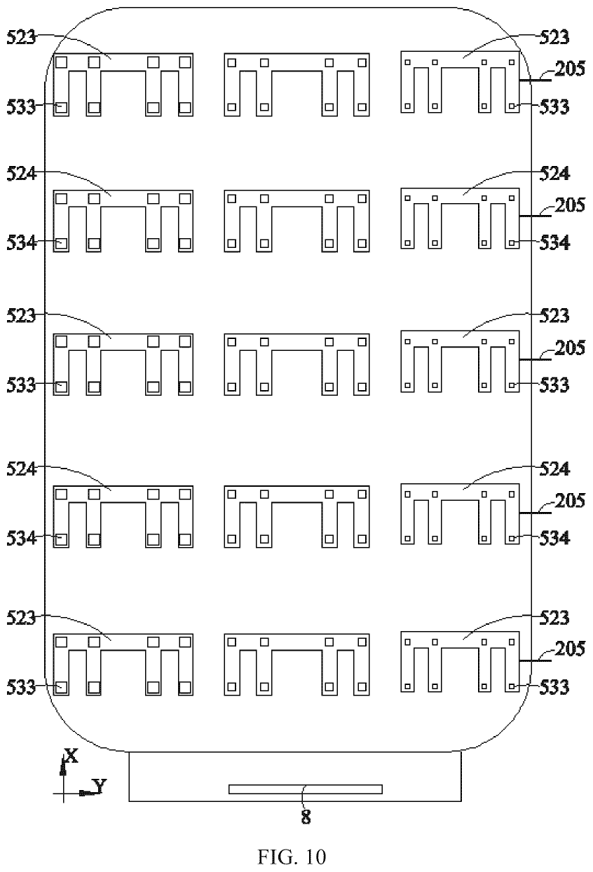

FIG. 9 illustrates the first bridging part 521 and the second bridging part 522 as well as the first via-hole 531 and the second via-hole 532; and FIG. 10 illustrates the third bridging part 523 and the fourth bridging part 524 as well as the third via-hole 533 and the fourth via-hole 534.

The first bridging part 521 is connected to two first touch electrodes 541 adjacent in the first direction X through the first via-hole 531. Specifically, the first bridging part 521 may be provided in a ‘T’ shape, such that the first bridging part 521 may include three connecting ends, in which a first connecting end may be connected to the second connecting wire 546 through at least one first via-hole 531, such that the first bridging part 521 is connected to another opposite end of the second connecting wire 546. A second connecting end and a third connecting end of the first bridging part 521 are symmetrically provided, and the second connecting end and the third connecting end are connected to two first touch sub-electrodes 5411 through at least two first via-holes 531 in one-to-one correspondence.

The second bridging part 522 is connected to two second touch electrodes 542 adjacent in the first direction X through the second via-hole 532. Specifically, the second bridging part 522 may be provided in a ‘T’ shape, such that the second bridging part may include three connecting ends, in which a first connecting end may be connected to the first connecting wire 545 through at least one second via-hole 532, such that the second bridging part 522 is connected to another opposite end of the first connecting wire 545. A second connecting end and a third connecting end of the second bridging part 522 are symmetrically provided, and the second connecting end and the third connecting end are connected to two second touch sub-electrodes 5421 through at least two second via-holes 532 in one-to-one correspondence.

The third bridging part 523 is connected to two third touch electrodes 543 adjacent in the second direction Y through the third via-hole 533. Specifically, the third bridging part 523 may be provided in a straight line, an end of the third bridging part 523 is connected to one third touch electrode 543 through the third via-hole 533, and the opposite end of the third bridging part 523 is connected to another third touch electrode 543 through the third via-hole 533. Two third bridging parts 523 may be provided to connect two adjacent third touch electrodes 543, i.e., the two third bridging parts 523 are connected between the two adjacent third touch electrodes 543. Moreover, the two third bridging parts 523 are provided substantially parallel. Of course, in some other exemplary embodiments of the present disclosure, the two third bridging parts 523 may also be provided crosswise; the third bridging part 523 may also be provided in a curved shape; three or more third bridging part 523 may be provided to connect two adjacent third touch electrodes 543, and the three or more third bridging parts 523 may be provided in parallel or crosswise.

The fourth bridging part 524 is connected to two fourth touch electrodes 544 adjacent in the second direction Y through the fourth via-hole 534. Specifically, the fourth bridging part 524 may be provided in a straight line, an end of the fourth bridging part 524 is connected to one fourth touch electrode 544 through the fourth via-hole 534, and the opposite end of the fourth bridging part 524 is connected to another fourth touch electrode 544 through the fourth via-hole 534. Two fourth bridging parts 524 may be provided to connect two adjacent fourth touch electrodes 544, i.e., the two fourth bridging parts 524 are connected between the two adjacent fourth touch electrodes 544. Moreover, the two fourth bridging parts 524 are provided substantially parallel. Of course, in some other exemplary embodiments of the present disclosure, the two fourth bridging parts 524 may also be provided crosswise; the fourth bridging part 524 may also be provided in a curved shape; three or more fourth bridging part 524 may be provided to connect two adjacent fourth touch electrodes 544, and the three or more fourth bridging parts 524 may be provided in parallel or crosswise.

Referring to FIGS. 7 and 8, since the first touch electrodes 541 are connected in the second touch layer 54 and the second touch electrodes 542 are connected in the second touch layer 54, the first bridging part 521 and the second bridging part 522 as well as the first via-hole 531 and the second via-hole 532 may not be provided, and it is sufficient to simply provide the third bridging part 523 and the fourth bridging part 524 as well as the third via-hole 533 and the fourth via-hole 534.

Of course, in some other example embodiments of the present disclosure, the connection between the third touch electrodes 543 may be achieved in the second touch layer 54, and the connection between the fourth touch electrodes 544 may be achieved in the second touch layer 54, in which case the third bridging part 523 and the fourth bridging part 524 as well as the third via-hole 533 and the fourth via-hole 534 may not be provided, and it is sufficient to simply provided the first bridging part 521 and the second bridging part 522 as well as the first via-hole 531 and the second via-hole 532.

In addition, since each touch unit is affected by an IR-Drop, the loads at different positions within the display area are not the same. When different positions are touched with a same extent, the touch signals at the different positions have a certain difference therebetween, that is, ΔCm (an amount of change in capacitance value) is not the same, which makes the touch response times at different positions in the display area are different, so that there is a sensitivity difference between respective positions. Moreover, as the screen size increases, the lengths of the touch wire in the display area and the touch lead in the peripheral area increase, therefore the effect from the IR-Drop is more significant, and the voltage drop between the distal and proximal ends of the signal input is more pronounced, making it difficult to achieve a high-quality touch function.

In an example embodiment, referring to FIGS. 1, 4, 5, and 7, the touch driving chip 8 is provided in the non-display area NA and is located at a side of the display area AA in the first direction X. The touch driving chip 8 is electrically connected to the first touch unit 201, the second touch unit 202, and the touch sensing lead 205, the specific connection relationship of which is not shown in the figures. The touch driving chip 8 is connected to the first touch unit 201 via the first touch driving lead 206, and the touch driving chip 8 is connected to the second touch unit 202 via the second touch driving lead 207. The touch driving chip 8 is connected to the third touch unit 203 and the fourth touch unit 204 via the touch sensing lead 205. The touch driving chip 8 inputs a touch driving signal via the first touch driving lead 206 and the second touch driving lead 207, and the touch driving chip 8 receives a touch sensing signal through the touch sensing lead 205.

Referring to FIG. 9, an area of an orthographic projection of the first via-hole 531 on the base layer 51 increases as a distance between the first via-hole 531 and the touch driving chip 8 increases. For example, the first via-hole 531 may be provided as a circular via-hole, and a diameter of the first via-hole 531 increases as the distance between the first via-hole 531 and the touch driving chip 8 increases; and the first via-hole 531 may be provided as a rectangular via-hole, and a side length of the first via-hole 531 increases as the distance between the first via-hole 531 and the touch driving chip 8 increases.

An area of an orthographic projection of the second via-hole 532 on the base layer 51 increases as a distance between the second via-hole 532 and the touch driving chip 8 increases. For example, the second via-hole 532 may be provided as a circular via-hole, and a diameter of the second via-hole 532 increases as the distance between the second via-hole 532 and the touch driving chip 8 increases; and the second via-hole 532 may be provided as a rectangular via-hole, and a side length of the second via-hole 532 increases as the distance between the second via-hole 532 and the touch driving chip 8 increases.

Of course, the first via-hole 531 and the second via-hole 532 may have other shapes, which will not be described herein.

Due to the IR-Drop, the closer to the touch driving chip 8, the larger the touch driving signal is, and the farther from the touch driving chip 8, the smaller the touch driving signal is. Such arrangement may effectively reduce the resistance of the first touch unit 201 at a position far from the touch driving chip 8, thereby effectively increasing the current of the first touch unit 201 at the position far from the touch driving chip 8, reducing the difference between the positions of the first touch unit 201 far from the touch driving chip 8 and close to the touch driving chip 8, and reducing the difference in ΔCm (the amount of change in capacitance value). Similarly, such arrangement may effectively reduce the resistance of the second touch unit 202 at a position far from the touch driving chip 8, thereby effectively increasing the current of the second touch unit 202 at the position far from the touch driving chip 8, reducing the difference between the positions of the second touch unit 202 far from the touch driving chip 8 and close to the touch driving chip 8, and reducing the difference in ΔCm (the amount of change in capacitance value), therefore the touch effect may be enhanced.

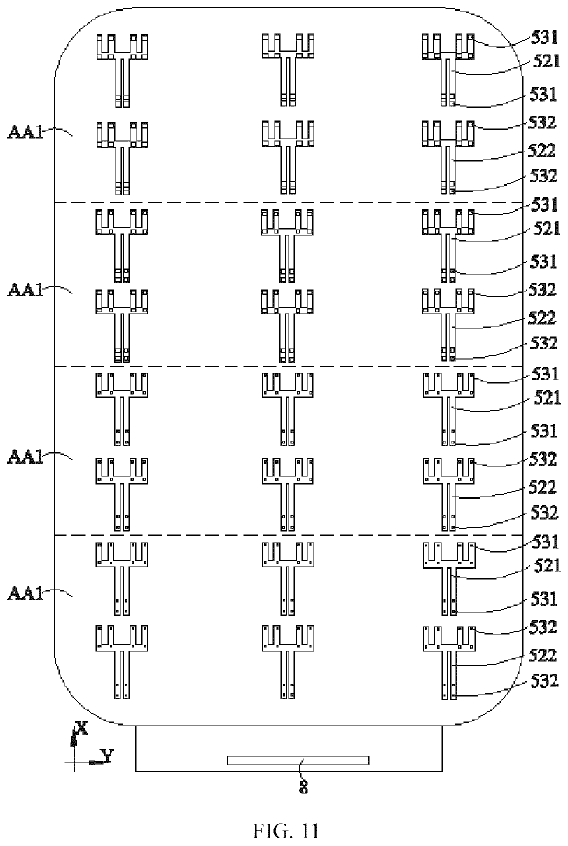

Referring to FIG. 11, the touch driving chip 8 is provided at a side of the display area AA in the first direction X, and in some other exemplary embodiments of the present disclosure, the display panel may include at least two first touch areas AA1 arranged sequentially along the first direction X. For example, the touch substrate 20 may include two first touch areas AA1 arranged sequentially along the first direction X; and the display panel may include three or more first touch areas AA1 arranged sequentially along the first direction X.

Areas of orthographic projections, on the base layer 51, of the first via-holes 531 located in a same first touch area AA1 are the same. For example, the first via-hole 531 may be provided as a circular via-hole, and the first via-holes 531 provided within the same first touch area AA1 have the same diameter; and the first via-hole 531 may be provided as a rectangular via-hole, and the first via-holes 531 provided within the same first touch area AA1 have the same side length.

Areas of orthographic projections, on the base layer 51, of the second via-holes 532 located in a same first touch area AA1 are the same. For example, the second via-hole 532 may be provided as a circular via-hole, and the second via-holes 532 provided within the same first touch area AA1 have the same diameter; and the second via-hole 532 may be provided as a rectangular via-hole, and the second via-holes 532 provided within the same first touch area AA1 have the same side length.

Moreover, areas of orthographic projections, on the base layer 51, of the first via-holes 531 located in different first touch areas AA1 increase as a distance between the first touch area AA1 and the touch driving chip 8 increases, i.e., the farther away the first touch area AA1 is from the touch driving chip 8, the larger the area of the orthographic projection, on the base layer 51, of the first via-hole 531 in the first touch area AA1 is, for example, the diameter or side length of the first via-hole 531 may increase.

Similarly, areas of orthographic projections, on the base layer 51, of the second via-holes 532 located in different first touch areas AA1 increase as a distance between the first touch area AA1 and the touch driving chip 8 increases, i.e., the farther away the first touch area AA1 is from the touch driving chip 8, the larger the area of the orthographic projection, on the base layer 51, of the second via-hole 532 in the first touch area AA1 is, for example, the diameter or side length of the second via-hole 532 may increase.

Such arrangement may reduce the design difficulty of the touch substrate 20, the difficulty of the manufacturing process of the touch substrate 20, and improve the production efficiency. Moreover, such arrangement may also reduce the difference between the positions of the first touch unit 201 far from the touch driving chip 8 and close to the touch driving chip 8, and reduce the difference in ΔCm (the amount of change in capacitance value); and may reduce the difference between the positions of the second touch unit 202 far from the touch driving chip 8 and close to the touch driving chip 8, and reduce the difference in ΔCm (the amount of change in capacitance value), and therefore the touch effect may be enhanced.

Moreover, areas of orthographic projections, on the base layer 51, of the first via-holes 531 connected to a same first bridging part 521 are the same, i.e., the plurality of first via-holes 531 connected to the same first bridging part 521 have the same size. Areas of orthographic projections, on the base layer 51, of the second via-holes 532 connected to a same second bridging part 522 are the same, i.e., the plurality of second via-holes 532 connected to the same second bridging part 522 have the same size. Such arrangement may reduce the design difficulty of the touch substrate 20, and the difficulty of the manufacturing process of the touch substrate 20, and improve the production efficiency can be improved.

Further, referring to FIG. 10, the touch sensing lead 205 is connected to the third touch unit 203 and the fourth touch unit 204 at a side thereof in the second direction Y. An area of orthographic projection of the third via-hole 533 on the base layer 51 increases as a distance between the third via-hole 533 and a connecting end of the touch sensing lead 205 increases. For example, the third via-hole 533 may be provided as a circular via-hole, and a diameter of the third via-hole 533 increases as the distance between the third via-hole 533 and the connecting end of the touch sensing lead 205 increases; and the third via-hole 533 may be provided as a rectangular via-hole, and a side length of the third via-hole 533 increases as the distance between the third via-hole 533 and the connecting end of the touch sensing lead 205 increases.

An area of orthographic projection of the fourth via-hole 534 on the base layer 51 increases as a distance between the fourth via-hole 534 and a connecting end of the touch sensing lead 205 increases. For example, the fourth via-hole 534 may be provided as a circular via-hole, and a diameter of the fourth via-hole 534 increases as the distance between the fourth via-hole 534 and the connecting end of the touch sensing lead 205 increases; and the fourth via-hole 534 may be provided as a rectangular via-hole, and a side length of the fourth via-hole 534 increases as the distance between the fourth via-hole 534 and the connecting end of the touch sensing lead 205 increases.

Of course, the third via-hole 533 and the fourth via-hole 534 may be of other shapes, which will not be described herein.

It is to be noted that, in the description of the third via-hole 533, the connecting end of the touch sensing lead 205 refers to a connecting position of the touch sensing lead 205 with the third touch unit 203, which is substantially a connecting; and in the description of the fourth via-hole 534, the connecting end of the touch sensing lead 205 refers to a connecting position of the touch sensing lead 205 with the fourth touch unit 204 position, which is substantially a connecting point.

Similarly, due to the IR-Drop, the closer to the connecting end of the touch sensing lead 205, the shorter the transmitting path of the touch sensing signal is, and the less affected by the IR-Drop; and the farther away from the connecting end of the touch sensing lead 205, the longer the transmitting path of the touch sensing signal is, and the more affected by the IR-Drop. Such arrangement may effectively reduce the resistances of the third touch unit 203 and the fourth touch unit 204 at the position far from the connecting end of the touch sensing lead 205, and thus may effectively increase the currents of the third touch unit 203 and the fourth touch unit 204 at the position far from the connecting ends of the touch sensing lead 205, reducing the difference between the positions of the third touch unit 203 and the fourth touch unit 204 far from the connecting ends of the touch sensing lead 205 and close to the connecting ends of the touch sensing lead 205, and reducing the difference in ΔCm (the amount of change in the capacitance value), therefore the touch effect may be enhanced.

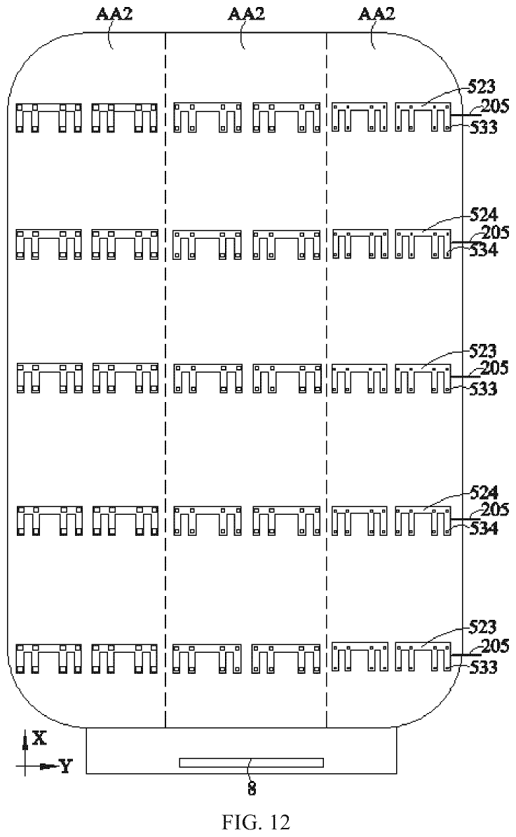

In some other exemplary embodiments of the present disclosure, referring to FIG. 12, the touch substrate 20 may include at least two second touch areas AA2 arranged sequentially along the second direction Y. For example, the touch substrate 20 may include two second touch areas AA2 arranged sequentially along the second direction Y; and the display panel may include three or more second touch areas AA2 arranged sequentially along the second direction Y.

Areas of orthographic projections, on the base layer 51, of the third via-holes 533 located in a same second touch area AA2 are the same. For example, the third via-hole 533 may be provided as a circular via-hole, and the third via-holes 533 located in the same second touch area AA2 have the same diameter; and the third via-hole 533 may be provided as a rectangular via-hole, and the third via-holes 533 located in the same second touch area AA2 have the same side length.

Areas of orthographic projections, on the base layer 51, of the fourth via-holes 534 located in a same second touch area AA2 are the same. For example, the fourth via-hole 534 may be provided as a circular via-hole, and the fourth via-holes 534 located in the same second touch area AA2 have the same diameter; and the fourth via-hole 534 may be provided as a rectangular via-hole, and the fourth via-holes 534 located in the same second touch area AA2 have the same side length.

Moreover, the areas of orthographic projections, on the base layer 51, of the third via-holes 533 located in different second touch areas AA2 increase as a distance between the second touch area AA2 and a connecting end of the touch sensing lead 205 increases, i.e., the farther the second touch area AA2 is away from the connecting end of the touch sensing lead 205, the larger the area of the orthographic projection, on the base layer 51, of the third via-hole 533 in the second touch area AA2, for example, the diameter or the side length of the third via-hole 533 may increase.

The areas of orthographic projections, on the base layer 51, of the fourth via-holes 534 located in different second touch areas AA2 increase as a distance between the second touch area AA2 and a connecting end of the touch sensing lead 205 increases, i.e., the farther the second touch area AA2 is away from the connecting end of the touch sensing lead 205, the larger the area of the orthographic projection, on the base layer 51, of the fourth via-hole 534 in the second touch area AA2, for example, the diameter or the side length of the fourth via-hole 534 may increase.

Such arrangement may reduce the design difficulty of the touch substrate 20 and the difficulty of the manufacturing process of the touch substrate 20, and improve the production efficiency. Moreover, the difference between the positions of the third touch unit 203 far from the connecting end of the touch sensing lead 205 and close to the connecting end of the touch sensing lead 205 may be reduced, and the difference in ΔCm (the amount of change in capacitance value) may also be reduced. Further, the difference between the positions of the fourth touch unit 204 far from the connecting end of the touch sensing lead 205 and close to the connecting end of the touch sensing lead 205 may be reduced, and the difference in ΔCm (the amount of change in capacitance value) may also be reduced. Therefore, the touch effect may be enhanced.

Moreover, the third via-holes 533 connected to the same third bridging part 523 have the same area of the orthographic projection on the base layer 51, i.e., the plurality of third via-holes 533 connected to the same third bridging part 523 have the same size. The fourth via-holes 534 connected to the same fourth bridging part 524 have the same area of the orthographic projection on the base layer 51, i.e., the plurality of fourth via-holes 534 connected to the same fourth bridging part 524 have the same size. Such arrangement may reduce the design difficulty of the touch substrate 20 and the difficulty of the manufacturing process of the touch substrate 20, and the production efficiency can be improved.

Referring to FIG. 7, in order to clearly distinguish between the first touch driving lead 206 and the second touch driving lead 207, the first touch driving lead 206 and the second touch driving lead 207 are shown by different line types. Two first touch driving leads 206 are correspondingly connected to the two opposite ends of the first touch unit 201, that is, each of the two opposite ends of the first touch unit 201 in the extension direction (the first direction X) is connected with the first touch driving lead 206, and the touch driving signal may be input to both opposite ends of the first touch unit 201 in the extension direction thereof, therefore the effect of the IR-Drop on the distal and proximal ends of the touch substrate may be reduced.

Two second touch driving leads 207 are correspondingly connected to the two opposite ends of the second touch unit 202, that is, each of the two opposite ends of the second touch unit 202 in the extension direction (the first direction X) is connected with the second touch driving lead 207, and the touch driving signal may be input to both opposite ends of the second touch unit 202 in the extension direction thereof, therefore the effect of the IR-Drop on the distal and proximal ends of the touch substrate may be reduced.

Of course, in some example embodiments of the present disclosure, the third touch unit 203 and the fourth touch unit 204 adjacent to each other form a group of touch sensing units, and each of the two ends of the touch sensing unit in the second direction Y is connected with the touch sensing lead 205, so that the touch sensing signal may be output from each of the two ends of the touch unit in the extension direction, therefore the effect of the IR-Drop on the distal and proximal ends of the touch substrate may be reduced.

Based on the same inventive concept, an example embodiment of the present disclosure provides a display device which may include the display panel as described in any one of the foregoing, and the specific structure of the display panel has been described in detail above, which therefore will not be repeated herein.

The specific type of the display device is not particularly limited, and the types of the display device commonly used in the art all are available, for example, a mobile device such as a mobile phone, a wearable device such as a watch, a VR device, and the like, and a person skilled in the art may select the display device according to the specific use thereof, which therefore will not be repeated herein.

It is to be noted that the display device includes other necessary parts and components in addition to the display panel. Taking a display as an example, it may specifically include, for example, a housing, a circuit board, a power cord, and so on, and a person skilled in the art may make corresponding additions according to the specific use of the display device, which therefore will not be repeated herein.

Compared with the related art, the beneficial effects of the display device provided by the example embodiments of the present disclosure are the same as the beneficial effects of the display panel provided by the above example embodiments, and will not be repeated herein.

A person skilled in the art may conceive of other embodiments of the present disclosure upon consideration of the specification and practice of the present disclosure disclosed herein. The present disclosure is intended to cover any variations, uses, or adaptations of the present disclosure that follow the general principle of the present disclosure and include a common knowledge or customary technical means in the art not disclosed herein. The specification and embodiments are to be regarded as exemplary only, and the true scope and spirit of the present disclosure is indicated by the appended claims.

1. A display panel, comprising:
a display substrate; and
a touch substrate, provided on a light exiting side of the display substrate, wherein the touch substrate comprises:
a plurality of first touch units, the first touch unit comprising a plurality of first touch electrodes connected sequentially along a first direction;
a plurality of second touch units, the second touch unit comprising a plurality of second touch electrodes connected sequentially along the first direction, and an input signal of the second touch unit being inverse in polarity to an input signal of the first touch unit;
a plurality of third touch units, the third touch unit comprising a plurality of third touch electrodes connected sequentially along a second direction, the third touch electrode forming a first touch capacitor with the first touch electrode, and the second direction intersecting the first direction; and
a plurality of fourth touch units, the fourth touch unit comprising a plurality of fourth touch electrodes connected sequentially along the second direction, and the fourth touch electrode forming a second touch capacitor with the second touch electrode.

2. The display panel according to claim 1, wherein an absolute value of the input signal of the second touch unit is the same as an absolute value of the input signal of the first touch unit.

3. The display panel according to claim 1, wherein the touch substrate comprises:
a base layer, provided on the light exiting side of the display substrate;
a first touch layer, provided on a side of the base layer away from the display substrate, comprising at least one of a group comprising a first bridging part and a second bridging part, or a group comprising a third bridging part and a fourth bridging part;
a touch insulating layer, provided on a side of the first touch layer away from the base layer, provided with at least one of a group comprising a plurality of first via-holes and a plurality of second via-holes, or a group comprising a plurality of third via-holes and a plurality of fourth via-holes; and
a second touch layer, provided on a side of the touch insulating layer away from the base layer, and comprising the first touch electrode, the second touch electrode, the third touch electrode, and the fourth touch electrode,
wherein the first bridging part connects two first touch electrodes adjacent in the first direction through the first via-hole, and the second bridging part connects two second touch electrodes adjacent in the first direction through the second via-hole; and the third bridging part connects two third touch electrodes adjacent in the second direction through the third via-hole, and the fourth bridging part connects two fourth touch electrodes adjacent in the second direction through the fourth via-hole.

4. The display panel according to claim 3, wherein the display panel has a display area and a non-display area located at at least one side of the display area, and the display panel further comprises:
a touch driving chip, provided in the non-display area, and electrically connected to the first touch unit, the second touch unit and a touch sensing lead,
wherein an area of an orthographic projection of the first via-hole on the base layer increases as a distance between the first via-hole and the touch driving chip increases, and an area of an orthographic projection of the second via-hole on the base layer increases as a distance between the second via-hole and the touch driving chip increases.

5. The display panel according to claim 3, wherein the display panel has a display area and a non-display area located at at least one side of the display area, and the display panel further comprises:
a touch driving chip, provided in the non-display area, located at a side of the display area in the first direction, and electrically connected to the first touch unit, the second touch unit and a touch sensing lead,
wherein the touch substrate comprises at least two first touch areas arranged sequentially along the first direction, areas of orthographic projections, on the base layer, of the first via-holes located in a same first touch area are the same, areas of orthographic projections, on the base layer, of the second via-holes located in the same first touch area are the same, areas of orthographic projections, on the base layer, of the first via-holes located in different first touch areas increase as a distance between the first touch area and the touch driving chip increases, and areas of orthographic projections, on the base layer, of the second via-holes located in the different first touch areas increase as a distance between the first touch area and the touch driving chip increases.

6. The display panel according to claim 3, wherein areas of orthographic projections, on the base layer, of the first via-holes connected to a same first bridging part are the same, and areas of orthographic projections, on the base layer, of the second via-holes connected to a same second bridging part are the same.

7. The display panel according to claim 3, wherein an area of an orthographic projection of the third via-hole on the base layer increases as a distance between the third via-hole and a connecting end of a touch sensing lead increases, and an area of an orthographic projection of the fourth via-hole on the base layer increases as a distance between the fourth via-hole and the connecting end of the touch sensing lead increases.

8. The display panel according to claim 3, wherein areas of orthographic projections, on the base layer, of the third via-holes connected to a same third bridging part are the same, and areas of orthographic projections, on the base layer, of the fourth via-holes connected to a same fourth bridging part are the same.

9. The display panel according to claim 3, wherein a touch sensing lead is connected to the third touch unit and the fourth touch unit at a side thereof in the second direction, the touch substrate comprises at least two second touch areas arranged sequentially along the second direction, areas of orthographic projections, on the base layer, of the third via-holes located in a same second touch area are the same, areas of orthographic projections, on the base layer, of the fourth via-holes located in the same second touch area are the same, areas of orthographic projections, on the base layer, of the third via-holes located in different second touch areas increase as a distance between the second touch area and a connecting end of the touch sensing lead increases, and areas of orthographic projections, on the base layer, of the fourth via-holes located in the different second touch areas increase as a distance between the second touch area and the connecting end of the touch sensing lead increases.

10. The display panel according to claim 3, wherein the second touch electrode and the first touch electrode are provided alternatively in the first direction, and the first touch electrode comprises:
two first touch sub-electrodes, sequentially arranged along the second direction, and spaced apart from each other; and
a first connecting part, connected between the two first touch sub-electrodes, and
the second touch electrode comprises:
two second touch sub-electrodes, sequentially arranged along the second direction, and spaced apart from each other; and
a second connecting part, connected between the two second touch sub-electrodes.

11. The display panel according to claim 10, wherein the second touch layer further comprises:
a first connecting wire, spaced apart from the two first touch sub-electrodes, provided between the two first touch sub-electrodes, having an end connected to the second connecting part and another opposite end connected to the second bridging part to connect two second touch electrodes adjacent in the first direction; and
a second connecting wires, spaced apart from the two second touch sub-electrodes, provided between the two second touch sub-electrodes, having an end connected to the first connecting part and another opposite end connected to the first bridging part to connect two first touch electrodes adjacent in the first direction.

12. The display panel according to claim 1, wherein the second touch electrode is staggered with the first touch electrode, and the first touch unit and the second touch unit are arranged alternatively in the second direction.

13. The display panel according to claim 1, wherein at least two adjacent third touch units form a group, and the third touch units in the group form a plurality of first touch capacitors with the plurality of first touch electrodes arranged in a row along the second direction; and at least two adjacent fourth touch units form a group, and the fourth touch units in the group form a plurality of second touch capacitors with the plurality of second touch electrodes arranged in a row along the second direction.

14. The display panel according to claim 1, wherein one third touch electrode is spaced apart from and provided adjacent to two adjacent first touch electrodes to form the first touch capacitor, and one fourth touch electrode is spaced apart from and provided adjacent to two adjacent second touch electrodes to form the second touch capacitor.

15. The display panel according to claim 1, wherein the touch substrate further comprises a plurality of touch sensing leads, a plurality of first touch driving leads and a plurality of second touch driving leads; each of the first touch driving leads is connected to an end of the first touch unit, and each of the second touch driving leads is connected to an end of the second touch unit; or two of the first touch driving leads are correspondingly connected to opposite ends of the first touch unit, and two of the second touch driving leads are correspondingly connected to opposite ends of the second touch unit, and
each of the touch sensing leads is at least connected to the third touch unit and the fourth touch unit adjacent to each other.

16. The display panel according to claim 1, wherein the third touch unit and the fourth touch unit adjacent to each other are a group of touch sensing units, and two ends of the touch sensing unit in the second direction each is connected to a touch sensing lead.

17. The display panel according to claim 1, wherein the plurality of first touch units are sequentially arranged along the second direction, the plurality of second touch units are sequentially arranged along the second direction, the plurality of third touch units are sequentially arranged along the first direction, and the plurality of fourth touch units are sequentially arranged along the first direction.

18. A display device, comprising the display panel according to claim 1.
